(19) United States
(12) Patent Application Publication
(10) Pub. No.: US 2008/0202551 A1
(43) Pub. Date: Aug. 28, 2008

(54) Method for cleaning solar cell substrates

(75) Inventor: Hyun-Seok Joo, Bucheon-si (KR)

Correspondence Address: GREER, BURNS & CRAIN, 300 S WACKER DR, 25TH FLOOR, CHICAGO, IL, 60606, US

(73) Assignee: Siltron Inc., Gumi-city (KR)

(21) Appl. No.: 12/005,664

(22) Filed: Dec. 27, 2007

(30) Foreign Application Priority Data
Dec. 29, 2006 (KR) 10-2006-0138081
Dec. 18, 2007 (KR) 10-2007-0133542

(51) Int. Cl. C23G 1/02; B08B 7/02

(52) U.S. Cl. 134/1.3; 134/3

(57) ABSTRACT

The present invention relates to a method for cleaning solar cell substrates comprising (S11) slicing an ingot for manufacturing solar cell substrates, which is hung from a slicing machine, into a plurality of substrates, and placing the substrates into a cleaning machine as the substrates are vertically hung down from the slicing machine parallel to each other; (S12) removing the cutting oil remaining on surfaces of the substrates placed vertically; (S13) activating the surfaces of the substrates for better cleaning of the surfaces of the substrates; and (S14) chemically etching the active surfaces of the substrates. The cleaning process is performed on the substrates directly as the substrates are placed in the slicing process. Therefore, the present invention prevents breakage or additional contamination of the substrates which may occur in an intermediate handling process, and effectively removes slurry between adjacent substrates and various stains on the surfaces of the substrates.

### BACKGROUND OF THE INVENTION

1. Field of the Invention

The present invention relates to a method for cleaning solar cell substrates, and in particular, to a method for cleaning solar cell substrates, in which a cleaning process is performed on substrates as the substrates are placed in a slicing machine, not unloaded from the slicing machine and transferred to a separate cleaning machine, thereby preventing breakage or contamination of the substrates occurring during an intermediate handling process to increase the yield of the substrates.

2. Description of the Related Art

To manufacture solar cell substrates, a slicing process is necessarily performed to slice an ingot into thin sections, i.e. substrates. When a sawing blade of a sawing machine (slicing machine) is contacted with the ingot in the slicing process, a cutting oil is used for effective sawing. The cutting oil includes fat-soluble and water-soluble. Recently, due to an environmental problem, a water-soluble cutting oil is preferred to a fat-soluble cutting oil.

However, the cutting oil may remain on surfaces of the substrates sliced from the ingot, and further slurry used in the slicing process may be attached to the surfaces of the substrates. Such pollutants should be removed from the surfaces of the substrates through a cleaning process so that the substrates are used as solar cell substrates. If a substrate is insufficiently cleaned and used as a solar cell substrate, pollutants remaining on surfaces of the substrate may reduce the performance of the solar cell substrate. Thus, it is preferable to perform a cleaning process after a slicing process. In particular, with thicknesses of substrates are reduced, more slurry remains between adjacent substrates, and thus pollutants are attached to surfaces of the substrates, which result in stains on the surfaces of the substrates. In the case that an antireflection coating is treated in a solar cell fabrication process, the stains may cause discoloration, thereby reducing the performance of a solar cell.

Meanwhile, to perform a cleaning process on substrates, the substrates are unloaded from a slicing machine one by one, loaded in a cassette shown in FIG. 1 and transferred to a cleaning machine using the cassette in an intermediate handling process.

However, during the intermediate handling process, the substrates may be broken or exposed to additional contamination. And, as the substrates should be unloaded from the slicing machine and loaded in the cassette one by one, when considering that several hundreds of substrates are produced from a single ingot, the operational effectiveness is reduced. Further, as thicknesses of substrates are reduced, the likelihood that the substrates are damaged in the intermediate handling process may be increased. Therefore, necessity was raised to effectively solve the problems involved in the intermediate handling process.

Studies have been continuously made in the related art to reduce breakage or contamination of substrates, improve operational effectiveness and effectively remove slurry or stain from the substrates, which may occur during the slicing process. In the above-mentioned technical background, the present invention was filed for a patent.

As described above, various pollutants or stains may remain on substrates sliced from an ingot. A cleaning process is required to remove the pollutants or stains. However, to perform the cleaning process, the substrates are transferred from a slicing machine to a separate cleaning system by a transfer means such as a cassette. In such an intermediate handling process, the substrates may be broken or contaminated. Therefore, it is an object of the present invention to prevent breakage or contamination of the substrates which may occur in the intermediate handling process and effectively remove the pollutants remaining on the substrates. It is another object of the present invention is to provide a method for cleaning solar cell substrates capable of solving the technical problems.

### SUMMARY OF THE INVENTION

In order to achieve the above-mentioned objects, a method for cleaning solar cell substrates comprises (S11) slicing an ingot for manufacturing solar cell substrates, which is hung from a slicing machine, into a plurality of substrates while providing a cutting oil, and placing the substrates into a cleaning machine as the substrate are vertically hung down from the slicing machine parallel to each other; (S12) removing the cutting oil remaining on surfaces of the substrates placed vertically; (S13) activating the surfaces of the substrates for better cleaning of the surfaces of the substrates; and (S14) chemically etching the active surfaces of the substrates.

Preferably, the cutting oil used in the step (S11) is polyethylene glycol (PEG) or polypropylene glycol (PPG). Preferably, the step (S12) uses at least one method selected from the group consisting of a spray method for spraying a deionized (DI) water having pressure of 2 to 3 kgf/cm² to upper portions of the substrates in a downstream direction, a bubbling method using air injection in the water from the bottom, a method for applying ultrasonic waves to a lower portion of the cleaning machine and a method for agitating the substrates placed in the cleaning machine. In the step (S13), preferably the surfaces of the substrates are treated using an alkali surfactant containing a silicon (Si) component under temperature conditions of 40 to 80° C. Preferably, the chemical etching in the step (S14) is performed using an etching liquid including sodium hydroxide of 5 to 80 weight %, hydrogen peroxide of 10 to 13 weight %, and a DI water of the remaining content.

### BRIEF DESCRIPTION OF THE DRAWINGS

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation.

FIG. 1 is a flow chart of a method for cleaning solar cell substrates according to the present invention.

### DESCRIPTION OF THE PREFERRED EMBODIMENT

Hereinafter, preferred embodiments of the present invention will be described in detail with reference to the accompanying drawings.

Conventionally, after an ingot is sliced into a plurality of substrates, the substrates are loaded in a separate means, for example a substrate cassette, and transferred to a separate cleaning machine using the substrate cassette. However, the present invention slices an ingot for manufacturing solar cell substrates into a plurality of substrates and cleans the substrates directly as they are placed after the slicing process. Thus, the present invention eliminates the need of a cutting oil when slicing the ingot, consequently the need of transferring the substrates to a separate cleaning machine to remove the cutting oil, and resultingly reduces breakage or contamination of the substrates which may occur during transferring or handling the substrates to increase the yield of the substrates. In particular, as thicknesses of the substrates are reduced, various yield-reducing factors may be intervened in the intermediate handling process, however the present invention can prevent the yield-reducing factors fundamentally through simplified process or handling and improve the operational efficiency.

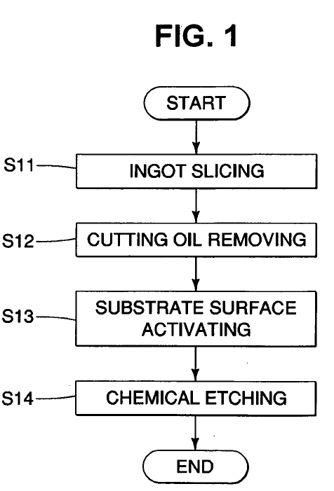

Referring to FIG. 1, first, an ingot for manufacturing solar cell substrates is hung from a slicing machine. While a cutting oil is provided to the ingot, the ingot is sliced into a plurality of substrates. The substrates are placed into a cleaning machine as they are vertically hung down from the slicing machine parallel to each other (S11). The cutting oil remaining on surfaces of the substrates placed vertically in the cleaning machine is removed (S12). For better cleaning of the surfaces of the substrates, the surfaces of the substrates are activated (S13). The active surfaces of the substrates are chemically etched (S14).

Preferably, the cutting oil used in the step (S11) is polyethylene glycol (PEG) or polypropylene glycol (PPG). In the embodiment of the present invention, polyethylene glycol (PEG) was used.

The step (S12) uses at least one method selected from the group consisting of a spray method for spraying a deionized (DI) water having pressure of 2 to 3 kgf/cm² to upper portions of the substrates in a downstream direction, a bubbling method using air injection in the water from the bottom, a method for applying ultrasonic waves to a lower portion of the cleaning machine and a method for agitating the substrates placed in the cleaning machine. By using the above-mentioned methods, the remaining cutting oil is effectively removed from the surfaces of the substrates. In the embodiment of the present invention, polyethylene glycol (PEG) cutting oil was used when slicing the ingot, and removed with the spray pressure of the DI water of 2 kgf/cm². In the case that the spray pressure is less than the above-mentioned minimum, it is not preferable because the cutting oil cleaning effect is insufficient. And, in the case that the spray pressure is more than the above-mentioned maximum, it is not preferable because the substrates may be damaged by mechanical shocks applied to the substrates. According to the present invention, the step (S12) is performed continuously after the step (S11) such that the substrates sliced in the step (S11) are not unloaded from the slicing machine, but placed in the slicing machine as sliced from the ingot. Thus, the present invention can solve the problems which may occur in the conventional cleaning method using a separate cassette.

In the step (S13), the surfaces of the substrates are treated using an alkali surfactant containing a silicon (Si) component, so that the surfaces of the substrates are activated to improve the cleaning performance. At this time, the alkali surfactant includes sodium hydroxide (NaOH) and potassium hydroxide (KOH). Preferably, the alkali surfactant has concentration of 10 to 50 weight %. In the embodiment of the present invention, sodium hydroxide (NaOH) having concentration of 20 weight % was used.

The chemical etching in the step (S14) is performed using an etching liquid including sodium hydroxide of 5 to 80 weight %, hydrogen peroxide of 10 to 13 weight %, and a DI water of the remaining content. The chemical etching using the etching liquid may effectively remove stains formed on the surfaces of the substrates. The embodiment of the present invention used an etching liquid including sodium hydroxide of 45 weight %, hydrogen peroxide of 10 weight %, and a DI water of the remaining content.

In the case that the content of sodium hydroxide contained in the etching liquid is less than the above-mentioned minimum, it is not preferable because the surfaces of the substrates are not effectively etched, and in the case that the content of sodium hydroxide contained in the etching liquid is more than the above-mentioned maximum, it is not preferable because the surfaces of the substrates are excessively etched, thereby causing spots on the surfaces of the substrates. And, In the case that the content of hydrogen peroxide contained in the etching liquid is less than the above-mentioned minimum, it is not preferable because the etching liquid is insufficiently mixed, and in the case that the content of hydrogen peroxide contained in the etching liquid is more than the above-mentioned maximum, it is not preferable because the surfaces of the substrates are excessively activated.

It should be understood that the detailed description and specific examples, while indicating preferred embodiments of the invention, are given by way of illustration only, since various changes and modifications within the spirit and scope of the invention will become apparent to those skilled in the art from this detailed description.

### APPLICABILITY TO THE INDUSTRY

According to the present invention, solar cell substrates are produced from an ingot and a cleaning process is performed on the substrates as the substrates are placed in the slicing process. Therefore, the present invention can prevent breakage or additional contamination of the substrates which may occur in an intermediate handling process, and effectively remove slurry between adjacent substrates and various stains on surfaces of the substrates.

What is claimed is:

1. A method for cleaning solar cell substrates, comprising:
(S11) slicing an ingot for manufacturing solar cell substrates, which is hung from a slicing machine, into a plurality of substrates while providing a cutting oil, and placing the substrates into a cleaning machine as the substrates are vertically hung down from the slicing machine parallel to each other;
(S12) removing the cutting oil remaining on surfaces of the substrates placed vertically;
(S13) activating the surfaces of the substrates for better cleaning of the surfaces of the substrates; and
(S14) chemically etching the active surfaces of the substrates.

2. The method for cleaning solar cell substrates according to claim 1,
wherein the cutting oil used in the step (SI 1) is polyethylene glycol (PEG) or polypropylene glycol (PPG).

3. The method for cleaning solar cell substrates according to claim 1,
wherein the step (S12) uses at least one method selected from the group consisting of a spray method for spraying a deionized (DI) water having pressure of 2 to 3 kgf/cm² to upper portions of the substrates in a downstream direction, a bubbling method using air injection in the water from the bottom, a method for applying ultrasonic waves to a lower portion of the cleaning machine and a method for agitating the substrates placed in the cleaning machine.

4. The method for cleaning solar cell substrates according to claim 1,
wherein, in the step (S13), the surfaces of the substrates are treated using an alkali surfactant containing a silicon (Si) component under temperature conditions of 40 to 80° C.

5. The method for cleaning solar cell substrates according to claim 1,
wherein the chemical etching in the step (S14) is performed using an etching liquid including sodium hydroxide of 5 to 80 weight %, hydrogen peroxide of 10 to 13 weight %, and a DI water of the remaining content.
